(19) United States
(12) Patent Application Publication
(10) Pub. No.: US 2026/0255853 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-Si (KR)

(72) Inventors: Eun Na YANG, Yongin-si (KR); Han Su KIM, Yongin-si (KR)

(21) Appl. No.: 19/548,204

(22) Filed: Feb. 24, 2026

(30) Foreign Application Priority Data
Feb. 25, 2025 (KR) 10-2025-0024330

(51) Int. Cl. H10K 59/80; H10K 59/122; H10K 59/35; H10K 59/38

(52) U.S. Cl. CPC H10K 59/877; H10K 59/122; H10K 59/352; H10K 59/38

(57) ABSTRACT

A display device includes a light-emitting element, and a color control portion arranged on the light-emitting element. The color control portion includes a bank including a color control hole, a dam structure disposed in the color control hole, a scattering layer in contact with a side surface of the dam structure and a side surface of the bank, and including a recess on an upper portion of the scattering layer, and a color control layer covering the scattering layer and the dam structure.

### CROSS-REFERENCE TO RELATED APPLICATION

This application claims priority to Korean Patent Application No. 10-2025-0024330 filed on February 25, 2025 in the Korean Intellectual Property Office (KIPO), the entire disclosure of which is incorporated by reference herein.

### BACKGROUND

### 1. Field

Embodiments of the present disclosure relate to a display device and an electronic device including the same. More particularly, embodiments of the present disclosure relate to a display device including a light-emitting element and a color control portion, and an electronic device including the same.

### 2. Descriptions of the Related Art

A display device such as an organic light emitting diode (OLED) display device and a liquid crystal display (LCD) device includes a display substrate including thin film transistors (TFTs) and various wirings. For example, a display structure including electrodes and emission layers may be formed on the display substrate.

For example, the OLED display device may include a light-emitting element including an organic emission layer. A color filter may be further provided to improve image characteristics or color characteristics of light emitted from the light-emitting element.

### SUMMARY

According to an aspect of the present disclosure, a display device having improved optical characteristics and image reliability is provided.

According to an aspect of the present disclosure, an electronic device including a display device with improved optical characteristics and image reliability is provided.

According to an embodiment, a display device includes a light-emitting element, and a color control portion arranged on the light-emitting element. The color control portion includes a bank including a color control hole, a dam structure disposed in the color control hole, a scattering layer disposed on a side surface of the dam structure and a side surface of the bank, and including a recess on an upper portion of the scattering layer, and a color control layer covering the scattering layer and the dam structure.

In an embodiment, a height of the dam structure may be smaller than a height of the bank.

In an embodiment, the scattering layer may contact the side surface of the dam structure, and may have a maximum height at a portion contacting the side surface of the dam structure.

In an embodiment, the scattering layer may not cover a top surface of the dam structure.

In an embodiment, the dam structure may include a liquid-repellent material.

In an embodiment, the scattering layer may include an inner scattering layer disposed in a central region of the color control hole, and an outer scattering layer disposed in an outer region of the color control hole.

In an embodiment, a width of the inner scattering layer may be greater than a width of the outer scattering layer.

In an embodiment, the recess of the scattering layer may include a first recess on an upper portion of the inner scattering layer and a second recess on an upper portion of the outer scattering layer, and a curvature of the first recess may be smaller than a curvature of the second recess.

In an embodiment, the outer scattering layer may have the recess, and the inner scattering layer may have a flat upper surface.

In an embodiment, the color control hole may include a first color control hole, a second color control hole, and a third color control hole. The color control layer may include a first color control layer, a second color control layer, and a third color control layer which may fill the first color control hole, the second color control hole, and the third color control hole, respectively, and may include different colorants from one another. A thickness of the third color control layer may be greater than a thickness of each of the first color control layer and the second color control layer.

In an embodiment, the first color control layer, the second color control layer, and the third color control layer may correspond to a red color layer, a green color layer, and a blue color layer, respectively.

In an embodiment, the dam structure may have a ring shape.

In an embodiment, a distance between inner surfaces of the dam structure along an imaginary straight line passing through a center of the color control hole may be greater than a distance between an outer surface of the dam structure and the side surface of the bank along the imaginary straight line.

In an embodiment, the dam structure may include a first dam structure and a second dam structure surrounding the first dam structure.

In an embodiment, the dam structure may include a plurality of line patterns or a plurality of separated pillar patterns.

In an embodiment, the display device may not include a polarizing plate or a polarizer.

According to an embodiment, a display device includes a light-emitting element, and a color control portion arranged on the light-emitting element. The color control portion includes a bank including a color control hole, a dam structure disposed in the color control hole, and a scattering color layer disposed on a side surface of the dam structure and a side surface of the bank, and including a recess on an upper portion of the scattering layer.

In an embodiment, the scattering color layer may include a binder resin, scattering particles, and a colorant.

According to an embodiment, an electronic device includes a display device, a memory, and a processor configured to execute data included in the memory to control an operation of the display device. The display device includes a light-emitting element, and a color control portion arranged on the light-emitting element. The color control portion includes a bank including a color control hole, a dam structure disposed in the color control hole, a scattering layer disposed on a side surface of the dam structure and a side surface of the bank, and including a recess on an upper portion of the scattering layer, and a color control layer covering the scattering layer and the dam structure.

In an embodiment, the electronic device may include virtual reality or augmented reality glasses, a smartphone, a tablet PC, a laptop, a TV, a desk monitor, smart glasses, a head-mounted display, a smart watch, or a vehicle display.

According to an embodiment of the present disclosure, a scattering layer including a recess having a concave curved surface may be formed in a color control hole defined by a bank. While the scattering layer may suppress image deterioration caused by reflection of external light, the recess formed on the upper portion of the scattering layer may suppress reduction in light efficiency due to the scattering layer. Additionally, the recess may enhance light scattering effect.

### BRIEF DESCRIPTION OF THE DRAWINGS

FIG. 1 is a schematic plan view of a display device according to an embodiment.

FIG. 2 is a schematic plan view illustrating a color control portion in a display device according to an embodiment.

FIG. 3 is a schematic cross-sectional view of a display device according to an embodiment.

FIG. 4 is a schematic cross-sectional view illustrating a light-emitting element of a display device according to an embodiment.

FIG. 5 is a schematic cross-sectional view illustrating a color control portion according to an embodiment.

FIG. 6 is a schematic cross-sectional view illustrating a color control portion according to an embodiment.

FIG. 7 is a schematic cross-sectional view illustrating a color control portion according to an embodiment.

FIG. 8 is a schematic cross-sectional view illustrating a color control portion according to an embodiment.

FIG. 9 is a partially enlarged plan view illustrating a color control portion according to an embodiment.

FIG. 10 is a partially enlarged plan view illustrating a color control portion according to an embodiment.

FIG. 11 is a partially enlarged plan view illustrating a color control portion according to an embodiment.

FIG. 12 is a partially enlarged plan view illustrating a color control portion according to an embodiment.

FIG. 13 is an exploded perspective view illustrating an electronic device according to an embodiment.

FIG. 14 is a block diagram of an electronic device according to an embodiment.

FIG. 15 is a schematic diagram of electronic devices according to embodiments.

### DETAILED DESCRIPTION OF THE EMBODIMENTS

Hereinafter, embodiments of the present disclosure will be described in more detail with reference to the accompanying drawings. The same reference numerals may be used for indicating the same elements in the drawings, and repeated descriptions of the same elements may be omitted. It should be understood that the embodiments disclosed in the accompanying drawings are merely exemplary and are intended to encompass all modifications, equivalents and alternatives falling within the spirit and technical feature of the present disclosure.

In the specification, it will be understood that when an element (or a region, a layer, a portion, or the like) is referred to as being "on", "connected to" or "coupled to" another element, it may be directly disposed on, connected to, or coupled to the other element, or indirectly on, connected to or coupled to the other elements with an intervening element disposed therebetween.

In the specification, it will also be understood that the terms, such as "first", "second", "below", "lower", "upper", "above," etc., are used in a relative sense to distinguish different elements or positions, and do not specify an absolute position or an absolute order.

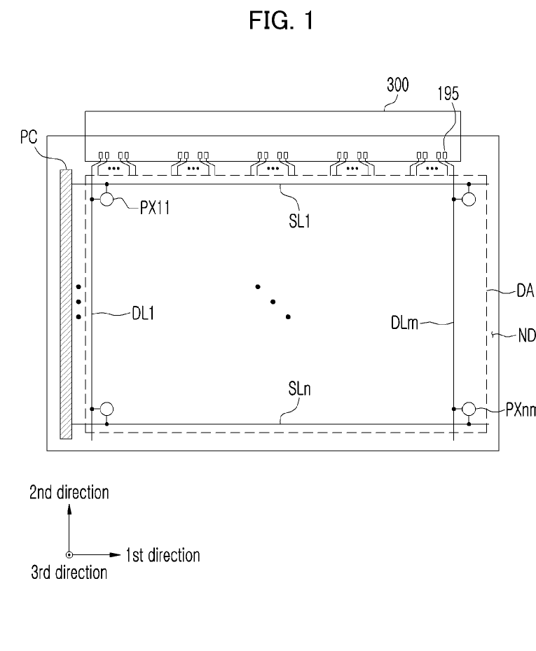

FIG. 1 is a schematic plan view of a display device according to an embodiment. For example, FIG. 1 is a plan view illustrating an arrangement of pixels of a display device according to an embodiment.

In FIG. 1, a first direction and a second direction may refer to two directions parallel to a display surface of a display device and perpendicular to each other. For example, the first direction may correspond to an X-direction (a row direction), and the second direction may correspond to a Y-direction (a column direction) of the display device. A third direction may refer to a direction perpendicular to the first direction and the second direction. The third direction may correspond to a Z-direction (a thickness direction) of the display device.

The definitions of the aforementioned directions may be applied in the same manner to the accompanying drawings.

Referring to FIG. 1, a plurality of pixels PX11 to PXnm may be arranged in a display area DA of the display device.

The display device according to an embodiment may include scan lines (or gate lines SL1 to SLn) extending in the first direction and forming first to nth rows, and data lines DL1 to DLm extending in the second direction and forming first to mth columns. The scan lines SL1 to SLn and the data lines DL1 to DLm may be arranged on a base substrate 100of the display device. Each of the pixels PX11 to PXnm may be connected to a corresponding scan line among a plurality of scan lines SL1 to SLn and a corresponding data line among a plurality of data lines DL1 to DLm.

Each of the pixels PX11 to PXnm may further include a pixel driving circuit including a transistor and a light-emitting element as described below. Although not illustrated in detail in FIG. 1, the pixel circuit may further include wirings such as a power line, a ground line, or the like.

Referring to FIG. 1, data lines DL1 to DLm may extend in the second direction, and scan lines SL1 to SLn may extend in the first direction. However, the arrangements of the scan lines SL1 to SLn and the data lines DL1 to DLm are not limited to the exemplified illustration in FIG. 1.

A peripheral circuit PC may be disposed in the non-display area NDA which surrounds at least one side of the display area DA. For example, the peripheral circuit PC may include a gate driving circuit. The gate driving circuit may be integrated into the display device by an oxide semiconductor gate (OSG) driver circuit process, an amorphous silicon gate (ASG) driver circuit process, or a polysilicon gate (PSG) driver circuit process.

The peripheral circuit PC may further include a data driver, a light-emitting driver, a power voltage generator, a timing controller, or the like.

The display device may further include a printed circuit board 300, and pads 195 positioned on one side of the non-display area NDA. A printed circuit board 300 may be electrically connected to the pads 195 through a heating-compression process using a conductive intermediate structure such as an anisotropic conductive film (ACF).

An integrated circuit (IC) including a data driver may be disposed on the printed circuit board 300. However, the present disclosure is not limited thereto. For example, an integrated circuit IC chip in the form of a chip-on-film (COF) may be mounted on the printed circuit board 300.

Hereinafter, for convenience of the explanation, the display device of the present disclosure may be an organic light-emitting display device. However, it should be understood that the display device of the present disclosure may be applied to various types of display devices such as an inorganic light-emitting display device and a quantum dot light-emitting display device, or the like.

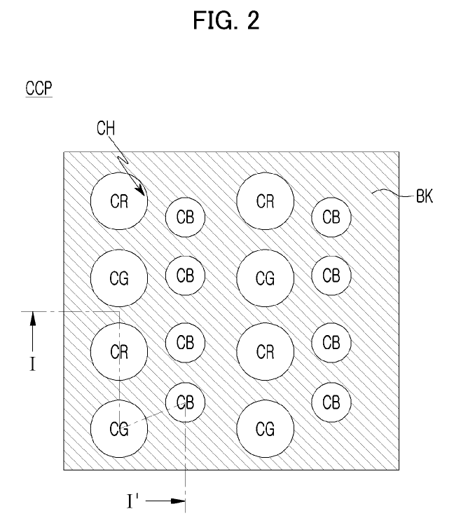

FIG. 2 is a schematic plan view illustrating a color control portion of a display device according to an embodiment.

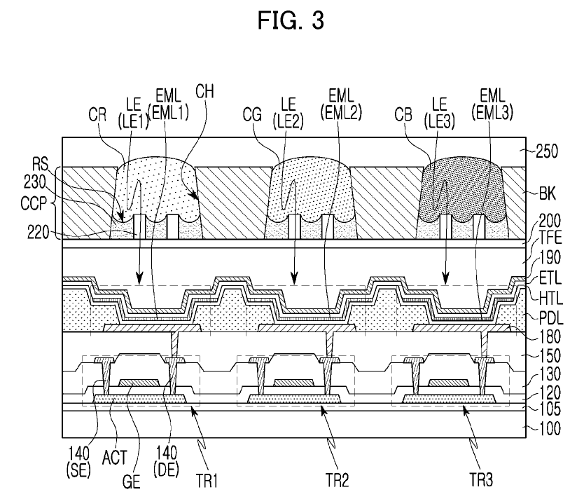

Referring to FIG. 2, a color control portion CCP may include a color control layer and a bank BK that may define the color control layer. The color control portion CCP may be disposed on an encapsulation layer TFE as illustrated in FIG. 3.

For example, the bank BK may include a polymer resin material or a photoresist material having light-shielding characteristics, and may be formed by a photo-lithography process including exposure and development processes.

The bank BK may include color control holes CH formed through the photo-lithography process. The color control layer may be disposed in each of the color control holes CH.

The color control layer may include a first color control layer CR, a second color control layer CG, and a third color control layer CB. According to an embodiment, the color control layer may serve as a colorant layer of a color filter.

The color control layer may be formed from a colored resin composition including a binder resin and a colorant material (e.g., dye and/or pigment). According to an embodiment, the color control layer may be formed by filling the colored resin composition into the color control hole CH by a printing process, such as an inkjet process.

According to an embodiment, the first color control layer CR, the second color control layer CG, and the third color control layer CB may be provided as a red colorant layer (a red color filter layer), a green colorant layer (a green color filter layer), and a blue colorant layer (a blue color filter layer), respectively.

For example, as illustrated in FIG. 2, the first color control layer CR and the second color control layer CG may be alternately and repeatedly arranged in, e.g., the second direction. The third color control layer CB may have an area smaller than that of each of the first color control layer CR or the second color control layer CG. The third color control layer CB may be arranged adjacent to the first color control layer CR or the second color control layer CG in, e.g., the first direction.

For example, the first color control layer CR and the second color control layer CG may be alternately and repeatedly arranged to form a color control column. The color control column may be repeatedly arranged in, e.g., the first direction. The third color control layers CB may be repeatedly arranged in the second direction between the adjacent color control columns.

According to an embodiment, a color control group may be defined by one first color control layer CR and one second color control layer CG neighboring in the second direction, and two third color control layers CB adjacent to the one first color control layer CR and the one second color control layer CG. The color control group may be repeatedly arranged in the first direction and the second direction.

The arrangement of the color control layers described with reference to FIG. 2 is provided as an example, and the structure of the color control portion included in the display device of the present inventive concepts is not limited to that illustrated in FIG. 2.

FIG. 3 is a schematic cross-sectional view of a display device according to an embodiment. For example, FIG. 3 is a cross-sectional view taken along a line I-I′ of FIG. 2 in a thickness direction (the third direction).

Referring to FIG. 3, the display device may include a base substrate 100, a pixel circuit, and a light-emitting element LE. The display device may include the color control portion CCP disposed on the light-emitting element LE.

The base substrate 100 may serve as a back-plane substrate of a display device. A glass substrate or a plastic substrate may be used as the base substrate 100. The base substrate 100 may include a polymer material having transparency and flexibility. In such a case, the base substrate 100 may be used in a transparent flexible display device.

For example, the base substrate 100 may include a polymer material such as polyimide, polysiloxane, an epoxy resin, an acrylic resin, polyester, or the like. According to an embodiment, the base substrate 100 may include polyimide.

A buffer layer 105 may be formed on the base substrate 100. The buffer layer 105 may prevent the penetration of moisture and the diffusion of impurities through the base substrate 100. The buffer layer 105 may be entirely formed over the display area DA and the non-display area NDA of the base substrate 100, and may entirely cover the top surface of the base substrate 100.

The buffer layer 105 may include, e.g., an inorganic insulating material, such as silicon oxide, silicon nitride, or silicon oxynitride. These inorganic insulating materials may be used alone or in a combination thereof to form the buffer layer 105.

The buffer layer 105 may have a multi-layered structure including a silicon oxide layer and a silicon nitride layer. The buffer layer 105 may be formed through a deposition process, such as a chemical vapor deposition (CVD) process, a sputtering process, an atomic layer deposition (ALD) process, or the like.

However, the present disclosure is not limited thereto. For example, the buffer layer 105 may include an organic layer, and may have a multi-layered structure including an organic layer and an inorganic layer.

The pixel circuit may include wirings including the scan lines and the data lines described with reference to FIG. 1, and transistors TR1, TR2 and TR3 each of which is electrically connected to the wirings. The transistors TR1, TR2 and TR3 may be electrically connected to light-emitting elements LE1, LE2 and LE3.

Each of the transistors TR1, TRb and TR3 may include an active layer ACT, a gate insulation layer 120 and a gate electrode GE.

The active layer ACT may be disposed on the buffer layer 105, and may be patterned by a photo-lithography process to be repeatedly/regularly arranged in each pixel. The active layer ACT may include a silicon compound such as polysilicon or amorphous silicon. A p-type dopant or an n-type dopant may be doped in a partial region of the active layer ACT, so that the active layer ACT may include a source region, a drain region, and a channel region.

The active layer ACT may include an oxide semiconductor, such as indium gallium zinc oxide (IGZO), zinc tin oxide (ZTO), or indium tin zinc oxide (ITZO).

The gate electrode GE may be disposed on the active layer 110, and the gate insulation layer 120 may be positioned between the active layer 110 and the gate electrode GE. As illustrated in FIG. 3, the gate insulation layer 120 may be provided continuously and commonly in a plurality of transistors TR1, TR2 and TR3, which correspond to different pixels emitting different colors. However, the present disclosure is not limited thereto. For example, the gate insulation layer 120 may be patterned to cover each of the active layer 110.

The gate electrode GE may overlap the channel region of the active layer ACT in the third direction. A scan signal may be transmitted from the scan line through the gate electrode GE.

The gate insulation layer 120 may be formed by the aforementioned deposition process and may include an inorganic insulating material, such as silicon oxide, silicon nitride, silicon oxynitride, or the like.

The source region and the drain region may be formed in the active layer ACT by using the gate electrode GE as an ion implantation mask.

An insulating interlayer 130 covering the gate electrode GE and the gate insulation layer 120 may be formed on the active layer ACT. A connection electrode 140 being in contact with or electrically connected to the active layer ACT may be formed on the insulating interlayer 130.

The insulating interlayer 130 may be formed by the aforementioned deposition process and may include an inorganic insulating material, such as silicon oxide, silicon nitride, silicon oxynitride, or the like. The insulating interlayer 130 may be formed in a single-layered structure or a multi-layered structure including different materials.

When the gate insulation layer 120 is formed in an individually patterned shape covering the active layer ACT in each pixel and the active layer ACT includes the oxide semiconductor, hydrogen (H) included in the insulating interlayer 130 may be diffused into or transferred to the active layer ACT during the formation of the insulating interlayer 130. Accordingly, a carrier concentration in the active layer ACT may be increased by the hydrogen, thereby allowing the source region and the drain region to be formed at side portions of the active layer ACT.

The connection electrode 140 may extend through the insulating interlayer 130, and may be connected to the active layer ACT. The connection electrode 140 may also extend through the gate insulation layer 120.

The connection electrode 140 may include a source electrode SE connected to or in contact with the source region of the active layer ACT, and a drain electrode DE connected to or in contact with the drain region of the active layer ACT.

Contact holes may be formed by partially etching the insulating interlayer 130. For example, the contact holes exposing the source region and the drain region, respectively, may be formed. The contact holes may also penetrate the gate insulation layer 120.

A metal layer filling the contact holes may be formed on the insulating interlayer 130, and the metal layer may be partially patterned through etching process to form the source electrode SE and the drain electrode DE. For example, a data signal may be transferred from the data line to each of the transistors TR1, TR2 and TR3 through the source electrode SE in each pixel.

The gate electrode GE and the connection electrode 140 may include a metal, such as Ag, Mg, Al, W, Cu, Ni, Cr, Mo, Ti, Pt, Ta, Nd, Sc, or the like, an alloy thereof, or a nitride thereof. The gate electrode GE and the connection electrode 140 may be formed by the aforementioned deposition process, such as a sputtering process. The gate electrode GE and/or the connection electrode 140 may have a multi-layered structure including different metal layers.

A planarization layer 150 covering the connection electrodes 140 may be formed on the insulating interlayer 130. The planarization layer 150 may include a via hole through which a pixel electrode 180 is electrically connected to the drain electrode DE.

The planarization layer 150 may include an organic material, such as polyimide, an epoxy resin, an acrylic resin, polyester, a siloxane resin, benzocyclobutene (BCB), or the like. The planarization layer 150 may be formed by a coating process such as a spin coating process or by the aforementioned deposition process.

The pixel electrode 180 may be formed in each pixel and may be electrically connected to the transistor TR1, TR2 or TR3. The pixel electrode 180 may be formed on the planarization layer 150 and may be electrically connected to the drain electrode DE.

For example, the planarization layer 150 may be partially etched to form a via hole exposing a top surface of the drain electrode DE. A conductive layer filling the via hole and including a metal or a transparent conductive oxide may be formed on a top surface of the planarization layer 150. The conductive layer may be etched to form the pixel electrode 180. The pixel electrode 180 may be connected to the drain electrode DE through the via hole.

The pixel electrode 180 may serve as an anode, and may include a high work function conductive material that facilitates hole injection. The pixel electrode 180 may be implemented as a transmissive electrode. The pixel electrode 180 may include a transparent conductive oxide, such as indium tin oxide (ITO), indium zinc oxide (IZO), zinc oxide (ZnO), indium tin zinc oxide (ITZO), or the like.

The pixel electrode 180 may be implemented as a translucent electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn, and Zn, or an alloy or a compound (e.g., LiF) including at least one therefrom.

The pixel electrode 180 may have a single-layered structure or a multi-layered structure. For example, the pixel electrode 180 may have a triple-layered structure of ITO/Ag/ITO or ITO/Al/ITO.

A pixel defining layer PDL covering a portion of a top surface of the pixel electrode 180 may be formed on the planarization layer 150. The pixel defining layer PDL may be formed to at least partially expose the top surface of the pixel electrode 180 so that a pixel may be defined. The pixel defining layer PDL may cover a peripheral portion of the pixel electrode 180.

For example, a pixel region or a light-emitting region may be defined by a sidewall of the pixel defining layer PDL. A pixel defining layer PDL may define and separate a first pixel including the first transistor TR1 and the first light-emitting element LE1, a second pixel including the second transistor TR2 and the second light-emitting element LE2, and a third pixel including the third transistor TR3 and the third light-emitting element LE3 from one another.

The first pixel, the second pixel and the third pixel may correspond to a red pixel, a green pixel, and a blue pixel, respectively.

The pixel defining layer PDL may include, e.g., an organic material such as a polysiloxane resin, a polyimide resin, an acrylic resin, or the like. The pixel defining layer PDL may include a colorant material such as a black pigment/dye dispersed in the resin material. The pixel defining layer PDL may include an inorganic layer such as a silicon oxide layer and/or a silicon nitride layer.

The pixel defining layer PDL may have a stepped structure as illustrated in FIG. 3.

An emission layer EML may be disposed on the exposed top surface of the pixel electrode 180. The emission layer EML may include an organic light-emitting material independently patterned for each of a red pixel, a green pixel and a blue pixel to generate light of different colors from each pixel.

The emission layer EML may include a first emission layer EML1 that may be included in the first pixel and include a red organic light-emitting material, a second emission layer EML2 that may be included in the second pixel and include a green organic light-emitting material, and a third emission layer EML3 that may be included in the third pixel and include a blue organic light-emitting material.

For example, the organic light-emitting material may include a host material that is excited by holes and electrons, and a dopant material that increases light-emission efficiency through absorption and release of energy.

According to an embodiment, a hole transport layer HTL may be disposed between the pixel electrode 180 and the emission layer EML. An electron transport layer ETL may be disposed on the emission layer EML.

The hole transport layer HTL and the electron transport layer ETL may extend continuously and commonly throughout a plurality of the light-emitting elements LE and the pixels.

For example, the hole transport layer HTL may include a hole transporting material, such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material, such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

The emission layer EML, the hole transport layer HTL, and/or the electron transport layer ETL may be formed through a process such as a thermal deposition, a vapor deposition, a vacuum deposition, a spin coating, an inkjet printing, a laser printing, a casting, a laser thermal transfer, or the like. For example, the pixel defining layer PDL having the stepped structure may enable a selective deposition of the emission layer EML for each pixel effectively.

According to an embodiment, a hole injection layer may be further formed between the pixel electrode 180 and the hole transport layer HTL. An electron injection layer may be further formed between a counter electrode 190 and the electron transport layer ETL.

A counter electrode 190 may be disposed on the pixel defining layer PDL and the emission layer EML. The counter electrode 190 may be formed on the electron transport layer ETL.

The counter electrode 190 may be a common electrode continuously and commonly formed on in a plurality of the light-emitting regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in a combination of two or more materials described above to form the counter electrode 190.

The counter electrode 190 may be implemented as a transmissive electrode, a translucent electrode, or a reflective electrode. The counter electrode 190 may have a single-layered structure or a multi-layered structure.

The light-emitting element LE may include the pixel electrode 180, the hole transport layer HTL, the emission layer EML, the electron transport layer ETL, and the counter electrode 190. For example, the light-emitting element LE may be electrically connected to the transistor of each pixel through the drain electrode DE.

The light-emitting elements LE may include the first light-emitting element LE1 including the first emission layer EML1, the second light-emitting element LE2 including the second emission layer EML2, and the third light-emitting element LE3 including the third emission layer EML3. For example, the first light-emitting element LE1 may emit red light, the second light-emitting element LE2 may emit green light, and the third light-emitting element LE3 may emit blue light.

An encapsulation layer TFE covering the light-emitting elements LE1, LE2 and LE3 may be disposed on the counter electrode 190. The encapsulation layer TFE may be disposed on the pixel defining layer PDL and the light-emitting elements LE1, LE2 and LE3 to protect the light-emitting elements LE1, LE2 and LE3 from moisture or oxygen.

The encapsulation layer TFE may include an inorganic layer including silicon nitride (SiNx), silicon oxide (SiOx), indium tin oxide, indium zinc oxide, or any combination thereof, an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof, or a combination of the inorganic layer and the organic layer described above.

The encapsulation layer TFE may be formed in a single-layered structure, or a multi-layered structure including a first inorganic layer, an organic layer and a second inorganic layer.

The color control portion may be disposed on the encapsulation layer TFE. The color control portion may include a base layer 200, the bank BK formed on the base layer 200, and the color control layers CR, CG and CB disposed in spaces (e.g., the color control holes CH) defined by the bank BK.

The base layer 200 may serve as a substrate for the bank BK and the color control layers CR, CG and CB, and the base layer 200 may include the inorganic insulating material.

As described with reference to FIG. 2, the first color control layer CR, the second color control layer CG and the third color control layer CB may be provided as a red colorant layer, a green colorant layer and a blue colorant layer, respectively. The first color control layer CR, the second color control layer CG and the third color control layer CB may overlap the first light-emitting element LE1, the second light-emitting element LE2 and the third light-emitting element LE3, respectively, in the third direction.

As described with reference to FIG. 2, the bank BK may include the color control holes CH, and the first color control layer CR, the second color control layer CG and the third color control layer CB may be filled into each of the color control holes CH, respectively. The color control hole CH may refer to an opening defined by adjacent banks BK.

According to an embodiment of the present disclosure, a scattering layer 230 may be formed on a bottom surface of the color control hole CH. In an embodiment, a scattering layer 230 may be formed between the color control layer CR, CG and CB and the base layer 200. For example, the scattering layer 230 may be formed on the base layer 200 within the color control hole CH. A dam structure 220 may be formed on the bottom surface of the color control hole CH. In an embodiment, a dam structure 220 may be formed between the color control layer CR, CG and CB and the base layer 200, and be positioned in the middle of the scattering layer 230. For example, the dam structure 220 may be formed on the base substrate 200 within the color control hole CH. The term “bottom surface” of the color control hole CH may refer to a surface of a layer which is exposed through the color control hole CH.

The scattering layer 230 may include a binder resin and light-scattering particles, such as TiO2, ZnO, Al2O3, SiO2, hollow silica, or the like, dispersed in the binder resin.

The scattering layer 230 may be formed within the color control hole CH, and be formed on a side surface of the dam structure 220 and a side surface of the bank BK. For example, the scattering layer 230 may be substantially defined or partitioned by the side surface of the dam structure 220 and the side surface of the bank BK. For example, the scattering layer 230 may be in contact with the side surface of the dam structure 220 and the side surface of the bank BK, and may not cover a top surface of the dam structure 220.

The dam structure 220 may be formed using a photosensitive transparent resin material containing, e.g., an acrylate group and/or an epoxy group. According to an embodiment, the dam structure 220 may be formed by a photo-lithography process or an inkjet process.

The dam structure 220 may include a liquid-repellent material. For example, a photosensitive transparent resin material containing a fluorine group such as a fluoroalkyl group may be used as the liquid-repellent material. For example, a resin or a compound containing a fluorine group such as a fluoroalkyl group may be included together with the photosensitive transparent resin material as a liquid-repellent material.

According to an embodiment, after forming the dam structure 220 on the bottom surface of the color control hole CH (e.g., within the color control hole CH), a composition for forming the scattering layer 230 may be injected into a space partitioned by the side surfaces of the bank BK and the dam structure 220 through an inkjet process.

As the binder resin included in the composition for forming the scattering layer 230 is attracted to the side surface of the dam structure 220 due to a liquid repellency of the dam structure 220, a height of a portion of the scattering layer 230 adjacent to the side surface of the dam structure 220 may be increased. Further, a height of a portion of the scattering layer 230 adjacent to the side surface of the bank BK may also be increased.

According to embodiments, the scattering layer 230 may have a maximum height at a portion in contact with the side surface of the dam structure 220 or the side surface of the bank BK.

Accordingly, an upper portion of the scattering layer 230 may have a recess RS having a concave curved surface between the side surfaces of the dam structure 220 facing each other and between the side surfaces of the bank BK and the dam structure 220. A surface of the recess RS (an upper surface of the scattering layer 230) may be concave toward the light-emitting element.

The scattering layer 230 may include a plurality of the recesses RS by the dam structure 220. The dam structure 220 may have a height less than a height of the bank BK.

The color control layers CR, CG and CB disposed within the color control hole CH may cover the dam structure 220 and the scattering layer 230.

The color control portion CCP may further include a protective layer 250 covering the bank BK and the color control layers CR, CG and CB. The protective layer 250 may include the aforementioned inorganic insulating material and/or organic insulating material.

According to an embodiment, the color control portion may be implemented as a color filter structure. For example, the first color control layer CR, the second color control layer CG, and the third color control layer CB may be implemented as a red color filter, a green color filter, and a blue color filter, respectively.

According to an embodiment, the color control portion may be provided as an on-cell film (OCF), and the display device may have a pol-less structure that does not include a polarizing plate or a polarizer.

The color control portion may be disposed on the light-emitting element LE so that the first color control layer CR, the second color control layer CG and the third color control layer CB overlap the red light-emitting element, the green light-emitting element and the blue light-emitting element, respectively.

According to an embodiment of the present disclosure, image defects due to diffraction of external light reflected by the scattering layer 230 may be reduced or suppressed. Accordingly, reflection of external light may be sufficiently reduced even without the polarizing plate, and color purity of each pixel may be improved.

Further, the recess RS may be formed on an upper portion of the scattering layer 230 by using the dam structure 220. The concave curved surface of the recess RS may prevent excessive scattering of a light emitted from the light-emitting element LE and improve light extraction efficiency. Additionally, the recess RS may further facilitate scattering of external light that is reflected.

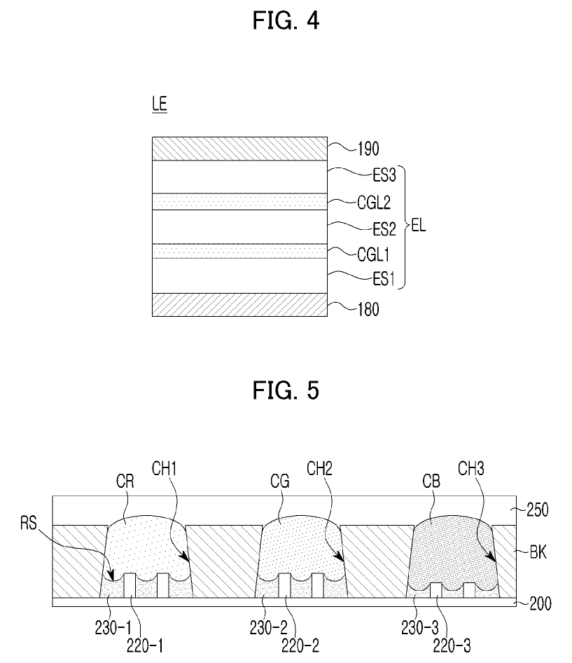

FIG. 4 is a schematic cross-sectional view illustrating a light-emitting element of a display device according to an embodiment.

Referring to FIG. 4, the light-emitting element LE of the display device described with reference to FIG. 3 may have a tandem structure.

As illustrated in FIG. 4, the light-emitting element LE may include a light-emitting portion EL disposed between the pixel electrode 180 and the counter electrode 190, and the light-emitting portion EL may include a plurality of light-emitting structures ES1, ES2 and ES3. Each of the light-emitting structures ES1, ES2 and ES3 may include the emission layer EML, and may further include the hole transport layer HTL and the electron transport layer ETL.

The light-emitting structures may include a first light-emitting structure ES1, a second light-emitting structure ES2, and a third light-emitting structure ES3.

Charge generation layers may be disposed between neighboring light-emitting structures. The charge generation layers may include a p-type charge generation layer and/or an n-type charge generation layer. The charge generation layers may include a first charge generation layer CGL1 between the first light-emitting structure ES1 and the second light-emitting structure ES2, and a second charge generation layer CGL2 between the second light-emitting structure ES2 and the third light-emitting structure ES3.

According to an embodiment, the first light-emitting structure ES1, the first charge generation layer CGL1, the second light-emitting structure ES2, the second charge generation layer CGL2, the third light-emitting structure ES3, and the counter electrode 190 may be sequentially stacked from the top surface of the pixel electrode 180.

The light-emitting portion EL included in the light-emitting element LE may be provided as a common layer shared by the first to third light-emitting elements LE1, LE2 and LE3. According to an embodiment, the light-emitting portion EL may emit blue light or white light, and color for each pixel may be implemented by the above-described color control portion.

Although FIG. 4 illustrates a light-emitting element LE having a triple-layered tandem structure of the light-emitting structures, the light-emitting element LE may have a two-layer tandem structure, or a tandem structure including four or more layers of the light-emitting structures.

Hereinafter, additional exemplary embodiments of configurations and structures of the color control portion CCP will be described. Detailed descriptions of configurations, structures and materials substantially the same as or similar to those described with reference to FIGS. 1 to 4 will be omitted.

FIG. 5 is a schematic cross-sectional view illustrating a color control portion according to an embodiment.

Referring to FIG. 5, the bank BK may include a first color control hole CH1, a second color control hole CH2, and a third color control hole CH3. The first color control layer CR, the second color control layer CG and the third color control layer CB may be formed in the first color control hole CH1, the second color control hole CH2 and the third color control hole CH3, respectively.

A first dam structure 220-1 and a first scattering layer 230-1 may be formed on a bottom surface of the first color control hole CH1. In an embodiment, the first dam structure 220-1 and the first scattering layer 230-1 may be formed between the first color control layer CR within the first color control hole CH1 and the base layer 200. A second dam structure 220-2 and a second scattering layer 230-2 may be formed on a bottom surface of the second color control hole CH2. In an embodiment, the second dam structure 220-2 and the second scattering layer 230-2 may be formed between the second color control layer CG within the second color control hole CH2 and the base layer 200. A third dam structure 220-3 and a third scattering layer 230-3 may be formed on a bottom surface of the third color control hole CH3. In an embodiment, the third dam structure 220-3 and the third scattering layer 230-3 may be formed between the third color control layer CB within the third color control hole CH3 and the base layer 200.

According to an embodiment, a height of the third dam structure 220-3 may be less than a height of the first dam structure 220-1. The height of the third dam structure 220-3 may be less than a height of the second dam structure 220-2.

Accordingly, a thickness or a height of the third scattering layer 230-3 positioned adjacent to the third dam structure 220-3 may be less than a thickness or a height of the first scattering layer 230-1. The thickness or the height of the third scattering layer 230-3 may be less than a thickness or a height of the second scattering layer 230-2.

A thickness of the third color control layer CB covering the third scattering layer 230-3 and the third dam structure 220-3 may be greater than a thickness of each of the first color control layer CR and the second color control layer CG.

As described above, the third color control layer CB may be provided as a blue colorant layer or a blue color filter layer. The thickness of the scattering layer 230 may be reduced in the third color control layer CB which corresponds to the blue pixel having relatively low emission efficiency. Accordingly, reduction in emission efficiency due to the scattering layer 230 may be suppressed or reduced while maintaining the above characteristics of the scattering layer 230.

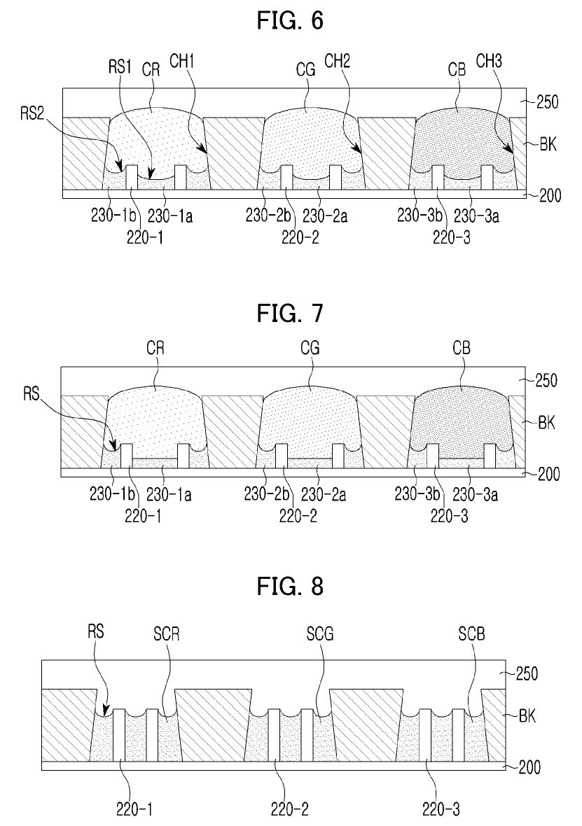

FIG. 6 is a schematic cross-sectional view illustrating a color control portion according to an embodiment.

Referring to FIG. 6, the scattering layer 230 may include an inner scattering layer and an outer scattering layer having different curvatures (a curvature of a recess surface) from each other. The inner scattering layer according to an embodiment may have a smaller curvature than that of an outer scattering layer.

The first scattering layer 230-1 may include a first inner scattering layer 230-1a and a first outer scattering layer 230-1b. A curvature of the first outer scattering layer 230-1b may be greater than that of the first inner scattering layer 230-1a.

The second scattering layer 230-2 may include a second inner scattering layer 230-2a and a second outer scattering layer 230-2b. A curvature of the second outer scattering layer 230-2b may be greater than that of the second inner scattering layer 230-2a.

The third scattering layer 230-3 may include a third inner scattering layer 230-3a and a third outer scattering layer 230-3b. A curvature of the third outer scattering layer 230-3b may be greater than that of the third inner scattering layer 230-3a.

For example, the inner scattering layers 230-1a, 230-2a and 230-3a may have a first recess RS1, and the outer scattering layers 230-1b, 230-2b and 230-3b may have a second recess RS2. A curvature of the first recess RS1 may be less than that of the second recess RS2.

According to an embodiment, a distance between the side surfaces of the dam structure 220 which define a space accommodating the inner scattering layers 230-1a, 230-2a and 230-3a may be greater than a distance between the side surface of the bank BK and the side surface of the dam structure 220 which define a space accommodating the outer scattering layers 230-1b,230-2b and 230-3b.

As another example, a distance between the side surfaces of the dam structure 220 which define a space accommodating the inner scattering layers 230-1a, 230-2a and 230-3a may be greater than a distance between the side surfaces of the dam structure 220 which define a space accommodating the outer scattering layers 230-1b, 230-2b, and 230-3b.

Accordingly, a width of the inner scattering layers 230-1a, 230-2a and 230-3a may be greater than a width of the outer scattering layers 230-1b, 230-2b and 230-3b. Further, during an inkjet printing of a scattering layer composition, the curvature of the inner scattering layers 230-1a, 230-2a and 230-3a may be adjusted to be relatively small.

A front light efficiency of the display device through the color control portion CCP may be increased through the inner scattering layer having a relatively small curvature. The scattering effect may be increased through the outer scattering layer having a relatively large curvature while effectively suppressing reflective diffraction.

The inner scattering layer may be disposed in a central region of the color control hole CH. In an embodiment, the inner scattering layer may be formed on a central region of the bottom surface of the color control hole CH. The outer scattering layer may be disposed in an outer region of the color control hole CH. In an embodiment, the outer scattering layer may be formed on an outer region of the bottom surface of the color control hole CH. The outer scattering layer may contact the side surface of the bank BK.

FIG. 7 is a schematic cross-sectional view illustrating a color control portion according to an embodiment.

Referring to FIG. 7, the inner scattering layers 230-1a, 230-2a and 230-3a may have substantially flat top surfaces. For example, a curvature of the inner scattering layers 230-1a, 230-2a and 230-3a may be substantially removed by further increasing the distance between the side surfaces of the dam structure 220 which define a space accommodating the inner scattering layers 230-1a, 230-2a and 230-3a.

Accordingly, the front light efficiency of the display device through the color control portion CCP may be further improved through the inner scattering layers 230-1a, 230-2a and 230-3a.

FIG. 8 is a schematic cross-sectional view illustrating a color control portion according to an embodiment.

Referring to FIG. 8, each of the scattering layer 230 and the color control layer CR, CG and CB described above may be substantially merged. As illustrated in FIG. 8, each of the scattering layer 230 and the color control layer CR, CG and CB may be formed as an integral layer.

According to an embodiment, an ink-type composition may be prepared by mixing a colorant material for forming the color control layer and scattering particles together in a binder resin. After the dam structures 220-1, 220-2 and 220-3 are formed, the ink-type composition described above may be injected into a space between the side surfaces of the dam structures 220-1, 220-2 and 220-3 and the side surfaces of the bank BK by an inkjet printing.

Accordingly, a scattering color layer, that is disposed on the side surfaces of the dam structures 220-1, 220-2 and 220-3 and the side surfaces of the bank BK, may be formed. The scattering color layer may include a first scattering color layer SCR, a second scattering color layer SCG and a third scattering color layer SCB which may be formed within the first color control hole CH1, the second color control hole CH2, and the third color control hole CH3, respectively.

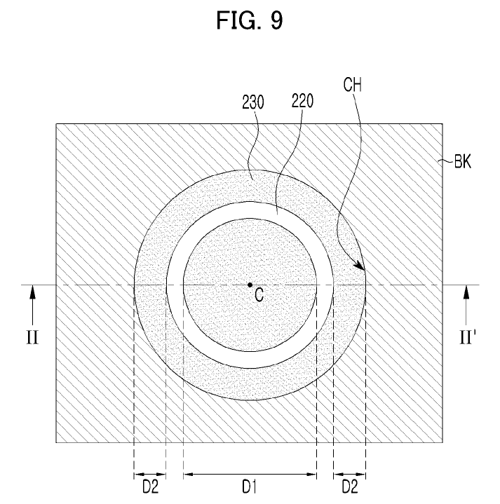

FIGS. 9 to 12 are partially enlarged plan views illustrating a color control portion according to an embodiment. In FIGS. 9 to 12, illustration and detailed description of the color control layer is omitted.

Referring to FIG. 9, the dam structure 220 may have a ring shape disposed within the color control hole CH in a plan view. For example, a cross-section of the color control portion CCP illustrated in FIGS. 5 to 8 may be a cross-section cut along a line II-II' of FIG. 9 in a thickness direction.

The II-II′ line may be a straight line passing through a center C of the bottom surface of the color control hole CH or a center of an inner space of the dam structure 220. The scattering layer 230 may be formed in an inner space of the dam structure 220 and in a space between an outer surface of the dam structure 220 and a side surface of the bank BK.

A distance between inner surfaces of the dam structure 220 along the line II-II’ may be indicated by a first distance D1. A distance between the outer surface of the dam structure 220 and the side surface of the bank BK along the line II-II’ may be indicated by a second distance D2.

According to an embodiment, the first distance D1 may be greater than the second distance D2. Accordingly, as described with reference to FIGS. 6 and 7, the curvature of upper surfaces of the inner scattering layers 230-1a, 230-2a and 230-3a formed in the inner space of the dam structure 220 may be relatively reduced or substantially flat.

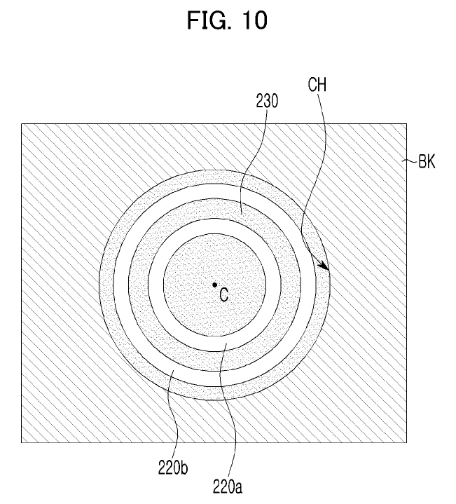

Referring to FIG. 10, a plurality of dam structures 220 each having a ring shape may be formed in the color control hole CH. According to embodiments, a first dam structure 220a and a second dam structure 220b may be disposed in the color control hole CH. The first dam structure 220a may be disposed within the second dam structure 220b.

In an embodiment, a distance between inner surfaces of the first dam structure 220a along an imaginary straight line passing through the center C (e.g., a radius of an inner circumference of the first dam structure 220a) may be greater than a distance between the first dam structure 220a and the second dam structure 220b.

Additionally, the distance between the inner surfaces of the first dam structure 220a along the imaginary straight line passing through the center C (e.g., the radius of the inner circumference of the first dam structure 220a) may be greater than a distance between the side surface of the bank BK and an outer surface of the second dam structure 220b.

Accordingly, as described with reference to FIGS. 6 and 7, the scattering layer having a relatively small curvature or a flat upper surface may be formed in the inner space of the first dam structure 220a.

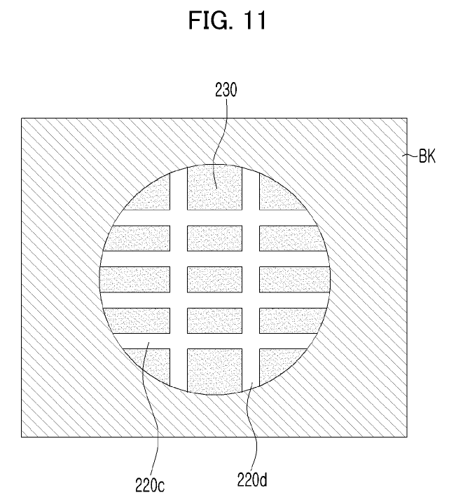

Referring to FIG. 11, the dam structure 220 may include line patterns crossing each other. For example, the dam structure 220 may include a first line pattern 220c and a second line pattern 220d extending in different directions and crossing each other.

In an embodiment, a plurality of the first line patterns 220c and a plurality of the second line patterns 220d may be arranged to cross each other and define a space in which the scattering layer 230 is formed.

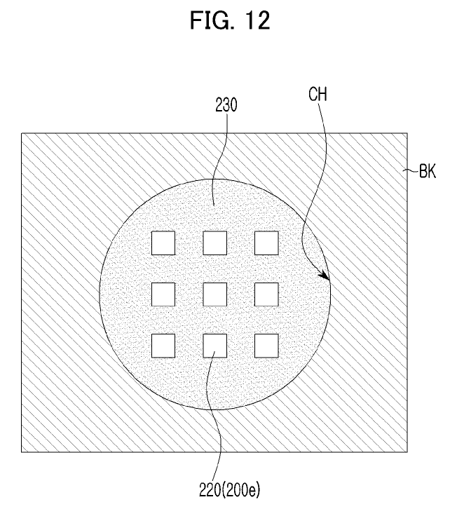

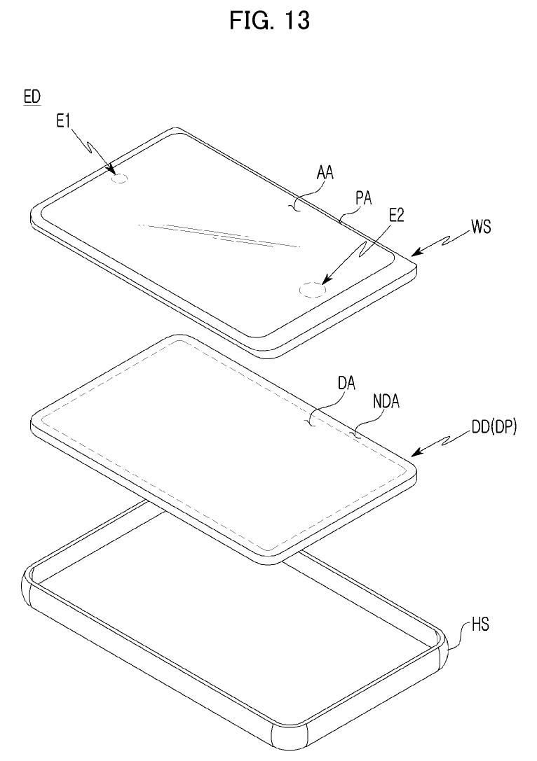

Referring to FIG. 12, the dam structure 220 may include a plurality of pillar patterns separated from each other. The recess of the scattering layer 230 may be formed between side surfaces of neighboring pillar patterns.

As the dam structure 220 may be formed as the pillar patterns separated from each other, light scattering effect may be implemented while increasing an aperture ratio in the color control hole CH.

FIG. 13 is an exploded perspective view illustrating an electronic device according to an embodiment.

According to exemplary embodiments, the electronic device ED may be implemented as a mobile phone (smart phone), a tablet, a PC, or the like, including the above-described display device.

Referring to FIG. 13, the electronic device may include a window structure WS, a display device DD, and a housing HS. The display device DD may include a display panel DP having the transistors and the light-emitting elements LE as described above. The housing HS, the display device DD, and the window structure WS may be sequentially stacked along the third direction.

The window structure WS may provide an external display surface recognized by a user, such as a viewing surface of a mobile phone, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may be a surface from which an image of the display device DD is substantially displayed and to which a user's touch/command is input. The peripheral area PA may substantially correspond to a bezel area of the display device.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

According to an embodiment, functional device areas E1 and E2 may be included in the active area AA of the window structure WS. For example, a first functional device area E1 may be included at one end portion of the active area AA and may correspond to, e.g., a camera hole. The second functional device area E2 may serve as a fingerprint sensing area.

For example, a sensor structure for a touch sensing or a fingerprint sensing may be disposed on the display panel DP or between the window structure WS and the display panel DP.

The housing HS may serve as a frame structure or a rear housing of the display device DD or the electronic device ED. A cover panel may be disposed between the housing HS and the display panel DP. The housing HS or the cover panel may include a plate (e.g., an SUS plate) that supports the display panel DP, the printed circuit board 300 (see FIG. 1), or the like. The housing HS or the cover panel may include an elastic body for absorbing shock of the display device DD.

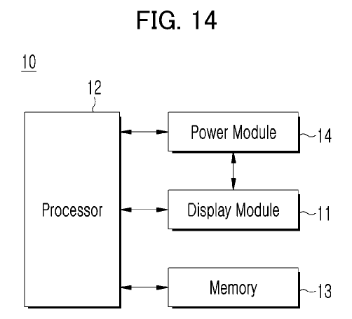

FIG. 14 is a block diagram of an electronic device according to an embodiment.

Referring to FIG. 14, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information necessary for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate a power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device and the processor 12, the memory 13 and the power module 14 may be provided in the form of another device in the electronic device 10 different from the display device.

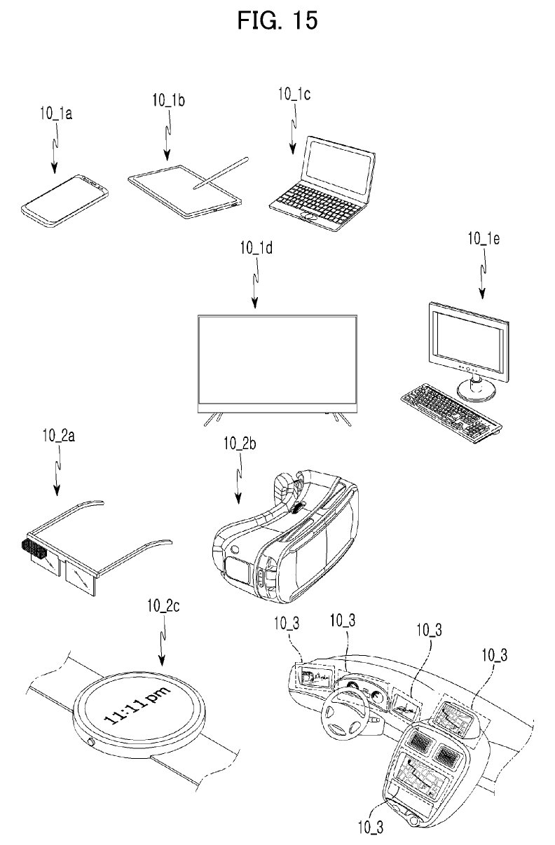

FIG. 15 is a schematic diagram of electronic devices according to embodiments.

Referring to FIG. 15, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) disposed at a vehicle instrument panel, a center fascia, a dashboard, etc., a head-up display, a room mirror display, or the like. The electronic device may include a virtual reality glass or an augmented reality glass.

In the above, description has been made with reference to embodiments of the inventive concept, but those skilled in the art may appreciate that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A display device, comprising:
a light-emitting element; and
a color control portion arranged on the light-emitting element,
wherein the color control portion comprising:
a bank including a color control hole;
a dam structure disposed in the color control hole;
a scattering layer disposed on a side surface of the dam structure and a side surface of the bank, the scattering layer having a recess on an upper portion of the scattering layer; and
a color control layer covering the scattering layer and the dam structure.

2. The display device of claim 1, wherein a height of the dam structure is smaller than a height of the bank.

3. The display device of claim 1, wherein the scattering layer contacts the side surface of the dam structure, and has a maximum height at a portion contacting the side surface of the dam structure.

4. The display device of claim 1, wherein the scattering layer does not cover a top surface of the dam structure.

5. The display device of claim 1, wherein the dam structure includes a liquid-repellent material.

6. The display device of claim 1, wherein the scattering layer comprises an inner scattering layer disposed in a central region of the color control hole, and an outer scattering layer disposed in an outer region of the color control hole.

7. The display device of claim 6, wherein a width of the inner scattering layer is greater than a width of the outer scattering layer.

8. The display device of claim 6, wherein the recess of the scattering layer comprises a first recess on an upper portion of the inner scattering layer and a second recess on an upper portion of the outer scattering layer, and
a curvature of the first recess is smaller than a curvature of the second recess.

9. The display device of claim 6, wherein the outer scattering layer has the recess, and the inner scattering layer has a flat upper surface.

10. The display device of claim 1, wherein the color control hole comprises a first color control hole, a second color control hole, and a third color control hole,
the color control layer comprises a first color control layer, a second color control layer, and a third color control layer which fill the first color control hole, the second color control hole, and the third color control hole, respectively, and include different colorants from one another, and
a thickness of the third color control layer is greater than a thickness of each of the first color control layer and the second color control layer.

11. The display device of claim 10, wherein the first color control layer, the second color control layer, and the third color control layer correspond to a red color layer, a green color layer, and a blue color layer, respectively.

12. The display device of claim 1, wherein the dam structure has a ring shape.

13. The display device of claim 12, wherein a distance between inner surfaces of the dam structure along an imaginary straight line passing through a center of the color control hole is greater than a distance between an outer surface of the dam structure and the side surface of the bank along the imaginary straight line.

14. The display device of claim 12, wherein the dam structure comprises a first dam structure and a second dam structure surrounding the first dam structure.

15. The display device of claim 1, wherein the dam structure comprises a plurality of line patterns or a plurality of separated pillar patterns.

16. The display device according to claim 1, wherein the display device does not include a polarizing plate or a polarizer.

17. A display device, comprising:
a light-emitting element; and
a color control portion arranged on the light-emitting element,
wherein the color control portion comprising:
a bank including a color control hole;
a dam structure disposed in the color control hole; and
a scattering color layer disposed on a side surface of the dam structure and a side surface of the bank, the scattering color layer having a recess on an upper portion of the scattering layer.

18. The display device according to claim 17, wherein the scattering color layer includes a binder resin, scattering particles, and a colorant.

19. An electronic device, comprising
a display device;
a memory; and
a processor configured to execute data included in the memory to control an operation of the display device,
wherein the display device comprises:
a light-emitting element; and
a color control portion arranged on the light-emitting element, and
wherein the color control portion comprising:
a bank including a color control hole;
a dam structure disposed in the color control hole;
a scattering layer disposed on a side surface of the dam structure and a side surface of the bank, the scattering layer having a recess on an upper portion of the scattering layer; and
a color control layer covering the scattering layer and the dam structure.

20. The electronic device of claim 19, wherein the electronic device includes virtual reality or augmented reality glasses, a smartphone, a tablet PC, a laptop, a TV, a desk monitor, smart glasses, a head-mounted display, a smart watch, or a vehicle display.
